(19) United States
(12) Patent Application Publication
(10) Pub. No.: US 2026/0293499 A1
(43) Pub. Date: Sep. 24, 2026

(54) DISPLAY PANEL AND FABRICATION METHOD THEREFOR, AND DISPLAY DEVICE

(71) Applicant: Yungu (Gu’an) Technology Co., Ltd., Langfang (CN)

(72) Inventors: Bin LIU, Langfang (CN); Jing ZHAO, Langfang (CN); Mengzhen LI, Langfang (CN)

(73) Assignee: Yungu (Gu’an) Technology Co., Ltd., Langfang (CN)

(21) Appl. No.: 19/403,960

(22) Filed: Nov. 30, 2025

(30) Foreign Application Priority Data
Mar. 21, 2025 (CN) 202510344583.8

(51) Int. Cl. H10K 59/80; H10K 59/12; H10K 59/122

(52) U.S. Cl. CPC H10K 59/876; H10K 59/1201; H10K 59/122

(57) ABSTRACT

The present disclosure provides a display panel and a fabrication method therefor, and a display device. The display panel includes a substrate, and isolation structures, encapsulation structures and light-emitting devices which are located on the substrate, The isolation structures include isolation openings, at least part of film layers of the light-emitting devices are located within the isolation openings, and the encapsulation structures are located on sides of the isolation structures away from the substrate and cover the light-emitting devices. Each light-emitting device and a portion of the encapsulation structure covering the light-emitting device form a microcavity structure, and the microcavity structures corresponding to the light-emitting devices emitting light of different colors are different. The solution can ameliorate the color shift problem of the display panel and increase the light extraction efficiency of the display panel.

### CROSS-REFERENCE TO RELATED APPLICATIONS

The present application claims priority to the Chinese Patent Application No. 202510344583.8, filed on Mar. 21, 2025, and the entire contents of the aforementioned application are hereby incorporated by reference in its entirety.

### FIELD

The present disclosure relates to the field of display, and in particular to a display panel and a fabrication method therefor, and a display device.

### BACKGROUND

An organic light-emitting device (OLED) is considered the next-generation flat panel display technology following liquid crystal, and has numerous unique advantages such as self-emission, full-solid-state, light weight, and flexibility. During the fabrication of conventional display panels, light-emitting pixel patterning is usually implemented by means of a fine metal mask (FMM). The FMM technology is mature and has abundant mass production experience. However, the FMM technology also has problems such as limited precision, high development cost, and long development cycle. Fine metal mask-free technology eliminates the limitations of conventional OLED processes on display screen size, resolution, and other screen performances, and has the advantages of high performance, full-size coverage, and agile delivery. The Chinese Patents CN118251982A, CN115666161A, CN116648095A, CN117062489A, CN118678742A, CN118785761A, CN115224220A, CN118678729A, CN118660529A and CN118660589A disclose related contents of the fine metal mask-free technology for reference.

An OLED display panel forms display frames by controlling light emission of light-emitting devices of different colors. Since the light-emitting performances of the light-emitting devices of different colors vary, how to enable all of the light-emitting devices of different colors to meet higher light-emitting performance requirements is a problem that urgently needs to be solved.

### SUMMARY

One embodiment of the present disclosure provides a display panel, including a substrate, and isolation structures, encapsulation structures and light-emitting devices which are located on the substrate. The isolation structures include isolation openings, at least part of film layers of the light-emitting devices are located within the isolation openings, and the encapsulation structures are located on sides of the isolation structures away from the substrate and cover the light-emitting devices. Each light-emitting device and a portion of the encapsulation structure covering the light-emitting device form a microcavity structure, and the microcavity structures corresponding to the light-emitting devices emitting light of different colors are different.

In the above embodiments, on the basis of the isolation structures, film layers of the microcavity structures in which the light-emitting devices emitting light of different colors are located can be fabricated with parameters (including thickness, refractive index, etc.), respectively, thereby improving chromaticity, light extraction efficiency, and so forth of sub-pixels in which the microcavity structures are located (the light-emitting devices serve as physical light-emitting structures thereof), to solve the problem of color shift of the display panel and improve the light extraction efficiency of the display panel.

In one embodiment of the present disclosure, the microcavity structures corresponding to the light-emitting devices emitting light of different colors have different microcavity lengths. In this way, the microcavity lengths of the microcavity structures are adjusted, to improve the chromaticity, light extraction efficiency, and so forth of the sub-pixels (the light-emitting devices are physical light-emitting structures thereof) corresponding to the microcavity structures.

In one embodiment of the present disclosure, the light-emitting device includes a first electrode, a light-emitting functional layer, and a second electrode sequentially stacked on the substrate, where the light-emitting functional layer and the second electrode of the light-emitting device are located in a corresponding isolation opening, the first electrode is a reflecting electrode, and the second electrode is a transparent electrode.

In one embodiment, a length of the microcavity structure corresponding to the light-emitting device is related to a wavelength of light generated by the light-emitting device.

In one embodiment, a length of the microcavity structure corresponding to the light-emitting device is positively correlated with a wavelength of the light generated by the light-emitting device.

In one embodiment, a length of the microcavity structure corresponding to the light-emitting device is an integral multiple of half a wavelength of light generated by the light-emitting device.

In one embodiment of the present disclosure, the light-emitting devices are classified into a first type of light-emitting devices, a second type of light-emitting devices and a third type of light-emitting devices which emit light of different colors, and wavelengths of light emitted by the first type of light-emitting devices, the second type of light-emitting devices and the third type of light-emitting devices decrease sequentially.

In one embodiment, the first type of light-emitting devices are configured to emit red light, the second type of light-emitting devices are configured to emit green light, and the third type of light-emitting devices are configured to emit blue light.

In one embodiment of the present disclosure, thicknesses of the second electrodes of the first type of light-emitting devices, the second type of light-emitting devices and the third type of light-emitting devices are different, or the thicknesses of the second electrodes of the first type of light-emitting devices, the second type of light-emitting devices and the third type of light-emitting devices are the same; and/or the second electrode includes magnesium and silver, and doping ratios of silver included in the second electrodes of the first type of light-emitting devices, the second type of light-emitting devices, and the third type of light-emitting devices are different, or and doping ratios of silver included in the second electrodes of the first type of light-emitting devices, the second type of light-emitting devices and the third type of light-emitting devices are the same, that is, by adjusting the content ratio of magnesium to silver in the second electrode, the reflectivity and transmittance of the second electrode can be adjusted, thereby adjusting the cavity length of the microcavity structure.

In one embodiment of the present disclosure, the doping ratios of silver included in the second electrodes of the first type of light-emitting devices, the second type of light-emitting devices and the third type of light-emitting devices increase sequentially.

In one embodiment, a content ratio of magnesium to silver included in the second electrode ranges from 1/10 to 10.

In one embodiment, microcavity orders of the microcavity structures corresponding to the first type of light-emitting devices, the second type of light-emitting devices and the third type of light-emitting devices are the same, and thicknesses of the second electrodes of the first type of light-emitting devices, the second type of light-emitting devices and the third type of light-emitting devices are the same; or the higher a microcavity order of the microcavity structure, the smaller a doping ratio of silver in the second electrode of the light-emitting device corresponding to the microcavity structure.

In one embodiment of the present disclosure, when microcavity orders of the microcavity structures respectively corresponding to the first type of light-emitting devices, the second type of light-emitting devices and the third type of light-emitting devices are the same, thicknesses of the second electrodes of the first type of light-emitting devices, the second type of light-emitting devices and the third type of light-emitting devices increase sequentially.

In the above embodiment, by adjusting the thicknesses of the second electrodes of the light-emitting devices emitting light of different colors, the cavity lengths of the microcavity structures corresponding to the light-emitting devices emitting light of different colors can be adjusted.

In one embodiment, the thicknesses of the second electrodes are in the range of 10-40 nm.

In one embodiment, the doping ratios of silver included in the second electrodes of the first type of light-emitting devices, the second type of light-emitting devices and the third type of light-emitting devices are the same.

In one embodiment of the present disclosure, when doping ratios of silver included in the second electrodes of the first type of light-emitting devices, the second type of light-emitting devices and the third type of light-emitting devices are the same, the higher the microcavity order of the microcavity structure, the smaller the thickness of the second electrode of the light-emitting device corresponding to the microcavity structure.

In one embodiment of the present disclosure, the light-emitting device includes at least one light-emitting functional layer, the light-emitting functional layer including a hole injection layer, a hole transport layer, an electron blocking layer, a light-emitting layer, a hole blocking layer, an electron transport layer and an electron injection layer which are sequentially stacked from the first electrode to the second electrode.

In one embodiment, the light-emitting device includes only one light-emitting functional layer.

In one embodiment, the light-emitting device includes at least two stacked light-emitting functional layers. In one embodiment, a charge generation layer is provided between adjacent light-emitting functional layers of the light-emitting device.

In one embodiment of the present disclosure, the light-emitting device further includes a cladding layer located between the second electrode and the encapsulation structure and covers the second electrode.

In one embodiment, the cladding layer is located within the isolation opening.

In one embodiment of the present disclosure, when microcavity orders of the microcavity structures respectively corresponding to the first type of light-emitting devices, the second type of light-emitting devices and the third type of light-emitting devices are the same, thicknesses of the cladding layers of the first type of light-emitting devices, the second type of light-emitting devices and the third type of light-emitting devices increase sequentially.

In the above embodiment, by adjusting the thicknesses of the cladding layers of the light-emitting devices emitting light of different colors, cavity lengths of the microcavity structures corresponding to the light-emitting devices emitting light of different colors can be adjusted.

In another embodiment of the present disclosure, the higher the microcavity order of the microcavity structure, the smaller the thickness of the cladding layer of the light-emitting device corresponding to the microcavity structure.

In one embodiment of the present disclosure, the light-emitting device further includes a modulation layer, the modulation layer being located between the cladding layer and the encapsulation structure and being located within the isolation opening. In one embodiment, the modulation layer includes lithium fluoride.

In one embodiment of the present disclosure, when the microcavity orders of the microcavity structures respectively corresponding to the first type of light-emitting devices, the second type of light-emitting devices and the third type of light-emitting devices are the same, thicknesses of the modulation layers of the first type of light-emitting devices, the second type of light-emitting devices and the third type of light-emitting devices decrease sequentially.

In another embodiment of the present disclosure, the higher the microcavity order of the microcavity structure, the smaller the thickness of the modulation layer of the light-emitting device corresponding to the microcavity structure.

In one embodiment, the thickness of the modulation layer is less than or equal to 100 nm.

In one embodiment of the present disclosure, the encapsulation structure includes a first encapsulation layer, the first encapsulation layer including encapsulation units respectively corresponding to the light-emitting devices, and the encapsulation units covering the isolation openings corresponding to the light-emitting devices.

In one embodiment, the encapsulation units respectively corresponding to adjacent light-emitting devices emitting light of different colors are spaced apart from each other.

In one embodiment of the present disclosure, the thicknesses and/or refractive indices of the encapsulation units respectively corresponding to the first type of light-emitting devices, the second type of light-emitting devices and the third type of light-emitting devices are different.

In one embodiment of the present disclosure, thicknesses of the encapsulation units respectively corresponding to the first type of light-emitting devices, the second type of light-emitting devices and the third type of light-emitting devices decrease sequentially.

In the above embodiment, by adjusting the thicknesses of the encapsulation units corresponding to the light-emitting devices emitting light of different colors, cavity lengths of the microcavity structures corresponding to the light-emitting devices emitting light of different colors can be adjusted.

In one embodiment of the present disclosure, refractive indices of the encapsulation units respectively corresponding to the first type of light-emitting devices, the second type of light-emitting devices and the third type of light-emitting devices decrease sequentially.

In the above embodiment, by adjusting the refractive indices of the encapsulation units corresponding to the light-emitting devices emitting light of different colors, the cavity lengths of the microcavity structures corresponding to the light-emitting devices emitting light of different colors can be adjusted.

In one embodiment, a difference between the refractive indices of any two of the encapsulation units respectively corresponding to the first type of light-emitting devices, the second type of light-emitting devices and the third type of light-emitting devices is greater than or equal to 0.05.

In one embodiment of the present disclosure, the encapsulation structure further includes a second encapsulation layer and a third encapsulation layer, the second encapsulation layer and the third encapsulation layer being located on a side of the first encapsulation layer away from the substrate and covering the first encapsulation layer and the isolation structure, and the second encapsulation layer being located between the first encapsulation layer and the third encapsulation layer.

In one embodiment, the first encapsulation layer and the third encapsulation layer are inorganic film layers, and the second encapsulation layer is an organic film layer.

In one embodiment, refractive indices of portions of the second encapsulation layer and the third encapsulation layer respectively corresponding to the first type of light-emitting devices, the second type of light-emitting devices and the third type of light-emitting devices are equal.

In one embodiment of the present disclosure, the isolation structure includes a support portion and a crown portion, the support portion being located between the substrate and the crown portion, the support portion being a conductive structure, a side surface of the support portion being connected to an edge portion of the second electrode, an orthographic projection of an end of the support portion facing the crown portion on the substrate being located within an orthographic projection of the crown portion on the substrate.

In one embodiment, an orthographic projection of the support portion on the substrate is located within an orthographic projection of the crown portion on the substrate.

In one embodiment, an orthographic projection of a surface of the support portion facing the crown portion on the substrate is located within an orthographic projection of a surface of the support portion facing the substrate on the substrate.

In one embodiment of the present disclosure, the display panel further includes a pixel defining layer, the pixel defining layer includes pixel openings respectively corresponding to the isolation openings, and the pixel openings are in communication with the corresponding isolation openings, the isolation openings and the corresponding pixel openings together limit the light-emitting functional layers and the second electrodes of the light-emitting devices.

In one embodiment, the pixel defining layer is an inorganic film layer.

In one embodiment, the pixel defining layer is located between the isolation structure and the substrate.

In one embodiment, an orthographic projection of each pixel opening on the substrate is located within an orthographic projection of the first electrode of the corresponding light-emitting device on the substrate, and an edge portion of the first electrode is located between the pixel defining layer and the isolation structure.

One embodiment of the present disclosure provides a fabrication method for a display panel, the fabrication method including: providing a substrate; forming first electrodes on a substrate; forming isolation structures having isolation openings on the substrate, the isolation openings respectively corresponding to the first electrodes; and fabricating light-emitting functional layers, second electrodes, and encapsulation units covering the isolation openings at the isolation openings in batches on the basis of the isolation structures, and the first electrode, the light-emitting functional layer and the second electrode stacked at each of the isolation openings form a light-emitting device, the encapsulation unit corresponding to each of the isolation openings forms a first encapsulation layer, and the first encapsulation layer is configured to form an encapsulation structure, where each of the light-emitting devices and a portion of the encapsulation structure covering the light-emitting device form a microcavity structure, and the light-emitting functional layers, the second electrodes and the corresponding encapsulation units of the light-emitting devices emitting light of different colors are fabricated in different batches on the basis of the isolation structures, and the microcavity structures corresponding to the light-emitting devices emitting light of different colors are different.

In the display panel obtained by the fabrication method, on the basis of the isolation structures, each film layer of the microcavity structures in which the light-emitting devices emitting light of different colors are located can be fabricated with parameters (including thickness, refractive index, etc.), respectively, thereby the microcavity length of each microcavity structure can be adjusted, improving chromaticity, light extraction efficiency, and so forth of sub-pixels in which the microcavity structures are located (the light-emitting devices serve as physical light-emitting structures thereof), to solve the problem of color shift of the display panel and improve the light extraction efficiency of the display panel.

In one embodiment of the present disclosure, fabricating light-emitting functional layers, second electrodes, and encapsulation units covering the isolation openings at the isolation openings in batches on the basis of the isolation structure includes: after forming the isolation structures, depositing a light-emitting functional material and an electrode material to respectively form a light-emitting functional structure layer and a second electrode structure layer; depositing a first insulating material film layer to form a first encapsulation structure layer; forming a photoresist layer on the first encapsulation structure layer and patterning the photoresist layer to form a photoresist pattern, the photoresist pattern covering part of the isolation openings; etching the first encapsulation structure layer, the second electrode structure layer and the light-emitting functional structure layer based on the photoresist pattern, to remove portions of the first encapsulation structure layer, the second electrode structure layer and the light-emitting functional structure layer not covered by the photoresist pattern, where remaining portions of the first encapsulation structure layer, the second electrode structure layer and the light-emitting functional structure layer respectively form the encapsulation units, the second electrodes and the light-emitting functional layers; removing the remaining photoresist pattern; and repeating the above steps to fabricate the light-emitting functional layers, the second electrodes and the encapsulation units at the remaining isolation openings in batches, where the light-emitting functional layers formed in different batches emit light of different colors, and all the encapsulation units form a first encapsulation layer.

In one embodiment of the present disclosure, the light-emitting devices are classified into a first type of light-emitting devices, a second type of light-emitting devices and a third type of light-emitting devices emitting light of different colors. In different batches, the thicknesses, and/or materials, and/or refractive indices of at least one of the encapsulation units, the second electrodes, and the light-emitting functional layers of the first type of light-emitting devices, the second type of light-emitting devices and the third type of light-emitting devices are controlled, respectively, and the microcavity structures corresponding to the first type of light-emitting devices, the second type of light-emitting devices and the third type of light-emitting devices are different.

One embodiment of the present disclosure provides a display device, including the display panel as claimed in the embodiments.

### BRIEF DESCRIPTION OF THE DRAWINGS

FIG. 1 is a structural schematic plane view of a display panel according to an embodiment of the present disclosure.

FIG. 2 is an enlarged view of part S1 of the display panel shown in FIG. 1 with one design.

FIG. 3 is a cross-sectional view of the display panel shown in FIG. 2 along line M1-N1.

FIG. 4 is an enlarged view of part S2 in a microcavity structure of the display panel shown in FIG. 3.

FIG. 5A is a cross-sectional view of the display panel shown in FIG. 2 along line M1-N1 with another design.

FIG. 5B is an enlarged view of part S2 in the microcavity structure of the display panel shown in FIG. 5A.

FIG. 6A is a cross-sectional view of the display panel shown in FIG. 2 along line M1-N1 with another design.

FIG. 6B is an enlarged view of part S2 in the microcavity structure of the display panel shown in FIG. 6A.

FIG. 7 is a cross-sectional view of the display panel shown in FIG. 2 along line M1-N1 with another design.

FIG. 8 is a flowchart of a fabrication method for a display panel according to an embodiment of the present disclosure.

FIG. 9 is a flowchart of another fabrication method for a display panel according to an embodiment of the present disclosure.

FIGS. 10A to 10H are process diagrams of a fabrication method for the display panel shown in FIG. 6A according to an embodiment of the present disclosure.

### LIST OF REFERENCE SIGNS

10—display panel; 11—active area; 12—non-active area; 20—microcavity structure; 100—substrate;
200—light-emitting device; 210—first electrode; 220—light-emitting functional layer; 221—first functional layer; HIL—hole injection layer; HTL-hole transport layer; EBL—electron blocking layer; 222—light-emitting layer; HBL—hole blocking layer; 223—second functional layer; ETL—electron transport layer; EIL—electron injection layer; 230—second electrode; 240—cladding layer; 250—modulation layer;
300—isolation structure; 301—isolation opening; 310—support portion; 320—crown portion; 400—pixel defining layer; 401—pixel opening;
500—encapsulation structure; 510—first encapsulation layer; 511—encapsulation unit; 520—second encapsulation layer; 530—third encapsulation layer; 600—photoresist pattern.

### DETAILED DESCRIPTION OF THE EMBODIMENTS

The embodiments of the specification will be clearly and completely described below in conjunction with the accompanying drawings in the embodiments of the specification. Apparently, the embodiments described are merely some rather than all of the embodiments of the specification.

In a display panel, types of light-emitting devices emitting light of different colors are provided. When the light-emitting devices are configured based on the microcavity effect, the microcavity lengths corresponding to the light-emitting devices emitting light of different colors are also different. However, due to limitations of the current fabrication processes, these light-emitting devices share common layers (share film layers), which restricts the design of the light-emitting devices with respect to the microcavity effect. As a result, the light-emitting devices emitting light of different colors exhibit different luminance decay at various viewing angles relative to the front view, leading to color shift.

The embodiments of the present disclosure provide a display panel and a fabrication method therefor, and a display device, to solve at least the above problems. The display panel includes a substrate, and isolation structures, encapsulation structures and light-emitting devices which are located on the substrate. The isolation structures include isolation openings, at least part of film layers of the light-emitting devices are located within the isolation openings, and the encapsulation structures are located on sides of the isolation structures away from the substrate and cover the light-emitting devices. Each light-emitting device and a portion of the encapsulation structure covering the light-emitting device form a microcavity structure, and the microcavity structures corresponding to the light-emitting devices emitting light of different colors are different. In the display panel, on the basis of the isolation structures, film layers of the microcavity structures in which the light-emitting devices emitting light of different colors are located can be fabricated with parameters (including thickness, refractive index, etc.), respectively, thereby improving chromaticity, light extraction efficiency, and so forth of sub-pixels in which the microcavity structures are located (the light-emitting devices serve as physical light-emitting structures thereof), to solve the problem of color shift of the display panel and improve the light extraction efficiency of the display panel.

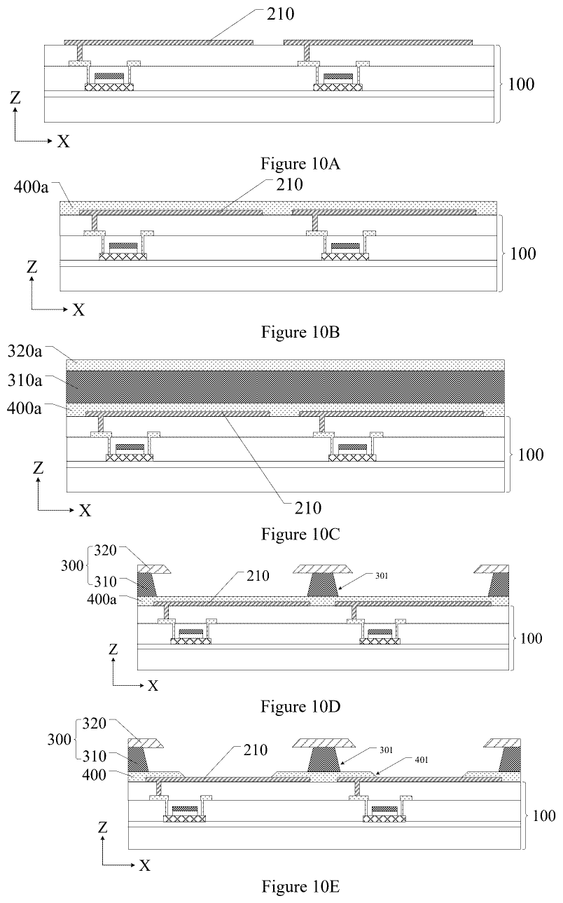

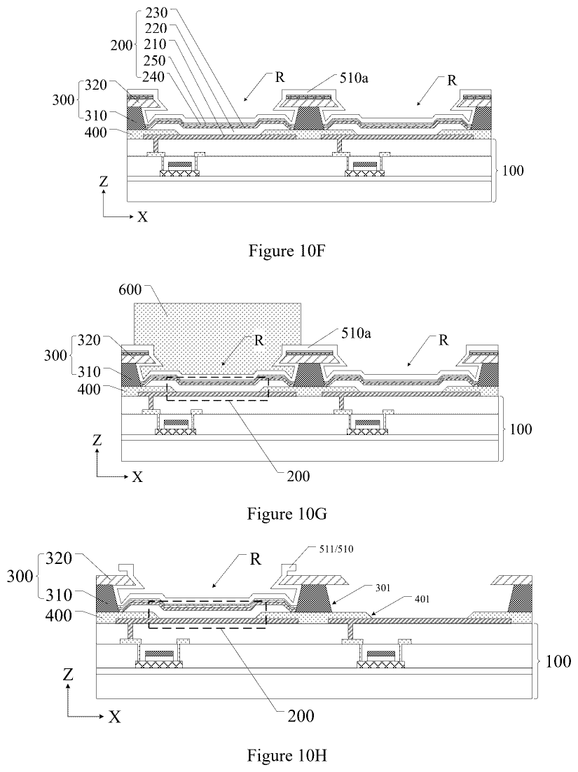

In addition, the functional film layers of adjacent light-emitting devices are separated by providing the isolation structures at gaps between the light-emitting devices, and in the evaporation process for part of the functional film layers of the light-emitting devices, it is only necessary to carry out the whole-surface evaporation on the display panel without the need to separately fabricate the functional film layer of each light-emitting device by means of a mask. In this process, there is no need to take into account the problem of alignment accuracy during evaporation, and thus the gaps between the light-emitting devices can be designed to have a small size to increase the PPI (the principle of which can refer to the relevant description of the following embodiments related to FIGS. 10A to 10H).

Structures of a display panel and a display device according to at least one embodiment of the present disclosure will be described below with reference to the drawings. In addition, in these drawings, a spatial rectangular coordinate system is established with the substrate of the display panel as a reference to more intuitively present the positional relationship of the relevant structures in the display panel. In the spatial rectangular coordinate system, an X-axis and a Y-axis are parallel to the plane where the substrate is located, and a Z-axis is perpendicular to the plane where the substrate is located.

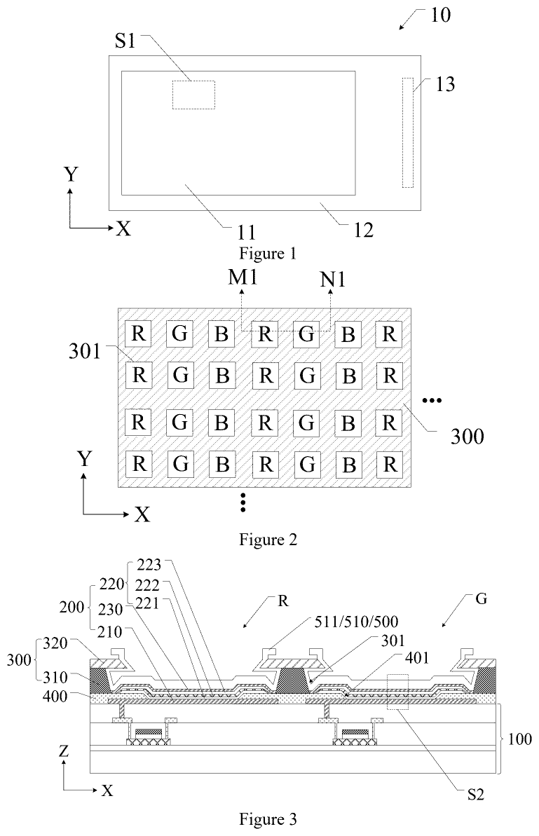

As shown in FIGS. 1 to 4, the display panel 10 includes an active area 11 and a non-active area 12 surrounding the active area 11. There may be sub-pixels (which may be referred to as subpixels) arranged in the active area 11, such as sub-pixels R, G and B, and physical structures of the sub-pixels may be light-emitting devices 200 in the embodiments below, and sub-pixels emitting light of different colors form a pixel (which may be referred to as a pixel unit, a large pixel, etc.). The density of the pixels arranged in the active area 11 represents the pixels-per-inch (PPI). For example, the non-active area 12 may include a bezel region of the display panel 10. It should be noted that after the fabrication of the display panel 10, at least part of the non-active area 12 (e.g., a bonding region 13) may be bent to a back side of the display panel 10, thereby reducing a bezel width of the display panel or visually achieving a bezel-free effect.

A physical structure of the display panel 10 includes a substrate 100, and isolation structures 300, encapsulation structures 500 and light-emitting devices 200 which are located on the substrate 100. The isolation structures 300 include isolation openings 301. At least a part of film layers (e.g., light-emitting functional layers, second electrodes, etc., as mentioned in the following embodiments) of the light-emitting devices 200 are located within the isolation openings 301, and the encapsulation structures 500 are located on the sides of the light-emitting devices 200 and the isolation structures 300 away from the substrate 100 and cover the light-emitting devices 200. Each light-emitting device 200 and a portion of the encapsulation structure 500 covering the light-emitting device 200 form a microcavity structure 20, and the microcavity structures 20 corresponding to the light-emitting devices 200 emitting light of different colors are different.

In at least one embodiment of the present disclosure, the microcavity structures 20 may differ in microcavity length, parameters of the included electrodes (e.g., second electrodes), optical film layers (e.g., cladding layer and modulation layer described below), etc. The microcavity length of the microcavity structure 20 is the sum of the thickness of all the film layers (in a direction perpendicular to the plane where the substrate 100 is located) from the light-emitting device 200 to the encapsulation structure 500.

It should be noted that the light-emitting devices 200 are main design structures with microcavity effects (constructive interference of light). In practical applications, the encapsulation structures 500 covering the light-emitting devices 200 affect the microcavity effects of the light-emitting devices 200. Therefore, in the embodiments of the present disclosure, all structures that affect the microcavity effects of the light-emitting devices 200 are taken into account as the microcavity structures 20.

When the light-emitting devices 200 are fabricated on the basis of the isolation structures 300, portions of the film layers corresponding to the light-emitting devices 200 emitting light of different colors are fabricated in different processes. Accordingly, in the fabrication process, the parameters (including thickness, refractive index, etc.) of the film layers of the microcavity structures 20 corresponding to the light-emitting devices 200 emitting light of different colors can be separately adjusted. In this way, the thickness, refractive index, and so forth of the film layer of the microcavity structure corresponding to each light-emitting device can be adjusted based on the color of the emitted light (wavelength of the emitted light) from the light-emitting device 200, thereby further adjusting the microcavity structures to adjust of the chromaticity, light extraction efficiency, and other properties of the sub-pixels corresponding to the respective light-emitting devices 200, alleviating the color shift problem of the display panel at different viewing angles and thus improving the display effect of the display panel.

In at least one embodiment of the present disclosure, the microcavity lengths of the microcavity structures 20 corresponding to the light-emitting devices 200 emitting light of different colors are different. Accordingly, the microcavity lengths of the microcavity structures 20 are adjusted, to improve the chromaticity, light extraction efficiency, and so forth of the sub-pixels corresponding to the microcavity structures 20.

It should be noted that in the embodiments of the present disclosure, the refractive indexes of the film layers may be measured by means of a device such as an ellipsometer. For example, the measurement principle of the ellipsometer is generally as follows. An ellipsometry method uses elliptically polarized light incident on a surface of a sample, and the thickness and refractive index of a film on a surface of the sample are then obtained based on changes of the polarization state (amplitude and phase) of reflected light.

The measurement steps of the ellipsometer are generally the following steps S1-S6.

In step S1, the ellipsometer is calibrated: calibrating the ellipsometer before measurement to ensure accurate measurement of the refractive index of the sample. A calibration method generally includes two steps: zero-offset adjustment and scale adjustment.

In step S2, a sample is prepared by placing the sample to be tested on a sample stage of the ellipsometer.

In step S3, a phase difference is measured, in which parameters of the instrument are adjusted and the ellipsometer outputs a minimum signal, where the ellipsometer measures the phase difference of the sample, and the phase difference is proportional to the refractive index of the sample.

In step S4, the refractive index is calculated by calculating the refractive index of the sample by means of a measured value of the phase difference according to the operating principle of the ellipsometer.

In step S5, measurements are performed and an average value is taken. In order to improve the accuracy of the measurement results, it is generally necessary to perform measurements and take an average value, where during the measurements, it is necessary to maintain the stability of the sample and avoid interference from external factors.

In step S6, environmental conditions are controlled, in which temperature and humidity have a certain influence on the refractive index of the sample, so it is important to control the environmental conditions during the measurements and maintain the environmental conditions stable.

The film thickness is also measured based on the principle of the elliptically polarized light. When the elliptically polarized light is incident on the surface of the sample, the polarization state of reflected light changes through reflections and refractions by a film. By analyzing the change, the thickness of the film can be determined.

For example, the measurement range of the ellipsometer usually includes ranges of thickness and refractive index of a transparent film, for example, the range of the thickness of the transparent film is 0-300 nm and the range of the refractive index is 1.30-2.49.

For example, the measurement accuracy of the ellipsometer is critical to the results, and the measurement accuracy of the ellipsometer generally can be up to ±2 nm.

For example, the ellipsometer can use a laser as a light source, such as a helium-neon laser or a semiconductor laser, which typically has a wavelength of 632.8 nm or 635 nm.

In at least one embodiment of the present disclosure, as shown in FIG. 3, the light-emitting device 200 includes a first electrode 210, a light-emitting functional layer 220, and a second electrode 230 sequentially stacked on the substrate 100, where the light-emitting functional layer 220 and the second electrode 230 of the light-emitting device 200 are located in a corresponding isolation opening 301, the first electrode 210 is a reflecting electrode, and the second electrode 230 is a transparent electrode. For example, the first electrode 210 is totally reflective, while the second electrode 230 is actually transflective, and light can exit while a microcavity effect function of the light-emitting device 200 is ensured, Accordingly, the second electrode 230 is visually transparent.

In an embodiment of the present disclosure, at least one light-emitting functional layer 220 is provided in the light-emitting device 200, that is, the light-emitting device 200 includes only one light-emitting functional layer 220; or the light-emitting device 200 includes at least two stacked light-emitting functional layers 220. It should be noted that in the case that the light-emitting device 200 includes at least two stacked light-emitting functional layers 220, a charge generation layer needs to be provided between adjacent light-emitting functional layers 220 of the light-emitting device 200.

For example, in at least one embodiment of the present disclosure, the first electrode 210 may be provided as an anode and the second electrode 230 may be provided as a cathode.

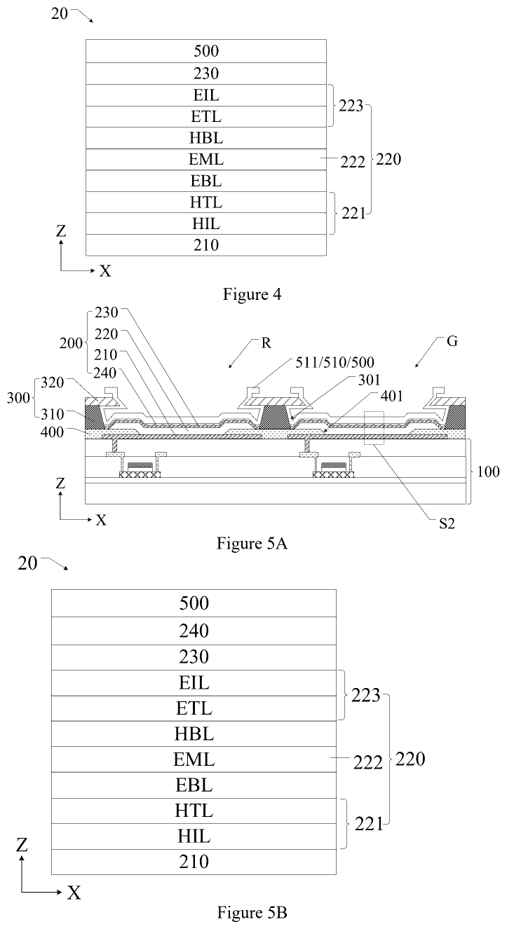

In at least one embodiment of the present disclosure, as shown in FIG. 3 and FIG. 4, the light-emitting functional layer 220 may also include a light-emitting layer 222 and a second functional layer 223. A first functional layer 221, the light-emitting layer 222 and the second functional layer 223 are sequentially stacked on the first electrode 210. The first functional layer 221 may include a hole injection layer HIL, a hole transport layer HTL, etc. The second functional layer 223 may include an electron transport layer ETL, an electron injection layer EIL, etc. It should be noted that one or more light-emitting layers 222 may be provided in the light-emitting device 200, and in the case of light-emitting layers are provided, the light-emitting device 200 may have higher light extraction efficiency.

For example, that light-emitting functional layer 220 may further include an electron blocking layer EBL located between the first electrode 210 and the light-emitting layer 222, and a hole blocking layer HBL located between the second electrode 230 and the light-emitting layer 222. Under this condition, specific positions of the electron blocking layer EBL and the hole blocking layer HBL in the light-emitting functional layer 220 may be adjusted according to the actual requirements. For example, as shown in FIG. 4, the light-emitting functional layer 220 includes a hole injection layer HIL, a hole transport layer HTL, an electron blocking layer EBL, a light-emitting layer 222, a hole blocking layer HBL, an electron transport layer ETL and an electron injection layer EIL which are sequentially stacked from the first electrode 210 to the second electrode 230.

In order to improve the light extraction efficiency of the light-emitting device 200 and reduce the power consumption of the device, microcavity resonance (constructive interference of reflected light in a microcavity) can be utilized to improve the light extraction efficiency, where the first electrode serves as a total reflection electrode of the microcavity structure 20, and the second electrode serves as a semi-reflection electrode of the microcavity structure 20. In this embodiment, the microcavity resonance can be achieved by adjusting the length of the microcavity structure 20 corresponding to the light-emitting device 200, where the length of the microcavity structure 20 corresponding to the light-emitting device 200 is related to the wavelength of the light generated by the light-emitting device 200 (e.g., in the case of the same order, may be a positive correlation), that is, in the case that the order of the microcavity structure is determined, the longer the wavelength of the light generated by the light-emitting device 200, the longer the length of the corresponding microcavity structure 20.

In at least one embodiment of the present disclosure, the microcavity resonance is achieved by adjusting the microcavity length corresponding to the light-emitting device 200, and the length of the microcavity structure 20 corresponding to the light-emitting device 200 is positively correlated with the wavelength of the light generated by the light-emitting device 200, i.e., the longer the wavelength of the light generated by the light-emitting device 200, the longer the length of the corresponding microcavity structure 20.

As an example, the length L of the microcavity structure 20 may be calculated by the following Equation 1:

$$2 L = 2 {\sum }_{i} {n}_{i} \times {d}_{i} + {ψ}_{1} + {ψ}_{2} = m \times λ$$

In the above-mentioned Equation 1,nᵢ is a refractive index of an i-th film layer of the microcavity structure 20, dᵢ is a thickness of the i-th film layer of the microcavity, ψ₁ and ψ₂ are reflection phase shifts of a total reflection electrode (first electrode 210) and a semi-transparent and semi-reflecting electrode (second electrode 230) of the microcavity structure 20, respectively, m is an order of a microcavity, taking a positive integer, and A is a resonant wavelength of the microcavity.

In at least one embodiment of the present disclosure, the length of the microcavity structure 20 corresponding to the light-emitting device 200 is an integral multiple of half the wavelength of the light generated by the light-emitting device 200. For example, in the case that m may be λ, L=λ, that is, the length L of the microcavity structure 20 is equal to the resonant wavelength of a second-order microcavity. When the resonant wavelength of the second-order microcavity is equal to the wavelength 2 of the light generated by the light-emitting device 200, it is possible to allow the reflected light to be completely constructively interfered in the light-emitting device 200, thereby increasing the light extraction efficiency of the light-emitting device 200 to reduce the power consumption of the display panel.

In at least one embodiment of the present disclosure, as shown in FIG. 2, at least part of the light-emitting devices 200 included in the display panel may be classified into a first type of light-emitting devices R, a second type of light-emitting devices G and a third type of light-emitting devices B which emit light of different colors. The wavelengths of the light emitted by the first type of light-emitting devices R, the second type of light-emitting devices G and the third type of light-emitting devices B decrease sequentially. For example, the first type of light-emitting devices R are configured to emit red light, the second type of light-emitting devices G are configured to emit green light, and the third type of light-emitting devices B are configured to emit blue light.

The enhancement effect of the microcavity structure 20 on the light emitted by the light-emitting device 200 can be measured using FWHM (full width at half maximum), which can be calculated according to Equation 2 below.

$$FWHM = \frac{{λ}^{2}}{2 L} \times \frac{1 - \sqrt{{R}_{1} {R}_{2}}}{π \sqrt[4]{{R}_{1} {R}_{2}}}$$

Where R₁ and R₂ are a reflectivity of the total reflection electrode (first electrode 210) and a reflectivity of a semi-transparent and semi-reflecting electrode (second electrode 230), the smaller the FWHM, the greater the enhancement degree of the microcavity structure 20 on the light emitted by the light-emitting device 200, and the narrower the wavelength range of the outgoing light.

In the embodiments of the present disclosure, no limitation is imposed on the film layers to be adjusted in the microcavity structures 20 (for example, parameters of the film layers corresponding to different types of light-emitting devices are different), and the film layers can be selected according to actual requirements. Several embodiments that can be used therein will be described below with reference to specific embodiments.

In at least one embodiment of the present disclosure, the lengths of the microcavity structures 20 corresponding to different types of light-emitting devices 200 can be adjusted by adjusting the parameters of the second electrodes 230. For example, the thicknesses of the second electrodes 230 of the first type of light-emitting devices R, the second type of light-emitting devices G and the third type of light-emitting devices B are different, or the thicknesses of the second electrodes 230 of the first type of light-emitting devices R, the second type of light-emitting devices G and the third type of light-emitting devices B are the same; and/or the second electrode 230 includes magnesium and silver, and doping ratios of silver (for example, a content ratio of magnesium to silver) included in the second electrodes 230 of the first type of light-emitting devices R, the second type of light-emitting devices G, and the third type of light-emitting devices B are different, or and doping ratios of silver (for example, a content ratio of magnesium to silver) included in the second electrodes 230 of the first type of light-emitting devices R, the second type of light-emitting devices G and the third type of light-emitting devices B are the same. That is, by adjusting the content ratio of magnesium to silver in the second electrode 230, the reflectivity and transmittance of the second electrode 230 can be adjusted, thereby adjusting the cavity length of the microcavity structure 20. It should be noted that the content ratio of magnesium to silver refers to the content of magnesium vs the content of silver.

For example, in some embodiments of the present disclosure, the doping ratios of silver included in the second electrodes 230 of the first type of light-emitting devices R, the second type of light-emitting devices G and the third type of light-emitting devices B increase sequentially. The lower the content (doping ratio) of silver, the smaller the reflectivity of the second electrode 230, and the higher the transmittance; and conversely, the higher the content of silver, the higher the reflectivity and the lower the transmittance.

For example, the content ratio of magnesium to silver included in the second electrode 230 ranges from 1/10 to 10, and the content ratio of magnesium to silver included in the second electrode 230 of the first type of light-emitting devices R, the second type of light-emitting devices G and the third type of light-emitting devices B is selected within the numerical range, and the luminance decay matching between the first type of light-emitting devices R, the second type of light-emitting devices G and the third type of light-emitting devices B can be higher, thereby more effectively alleviating the color shift problem. It should be noted that, in the embodiments of the present disclosure, the content ratio of magnesium to silver in the second electrode 230 can be adjusted according to actual process requirements, and thus is not limited to the numerical range.

For example, when the doping ratios of silver included in the second electrodes 230 of the first type of light-emitting devices R, the second type of light-emitting devices G and the third type of light-emitting devices B increase sequentially, if the microcavity orders of the microcavity structures 20 respectively corresponding to the first type of light-emitting devices R, the second type of light-emitting devices G and the third type of light-emitting devices B are the same, and the thicknesses of the second electrodes 230 of the first type of light-emitting devices R, the second type of light-emitting devices G and the third type of light-emitting devices B can be designed to be the same, thereby simplifying the fabrication process of the display panel and controlling process costs.

For example, when the doping ratios of silver in the second electrodes 230 of the first type of light-emitting devices R, the second type of light-emitting devices G and the third type of light-emitting devices B increase sequentially, the higher the microcavity order of the microcavity structure 20, the smaller the doping ratio of silver in the second electrode 230 of the corresponding light-emitting device 200. In this way, by adjusting the reflectivity and transmittance of the second electrode, the cavity length of the microcavity structure can be adjusted to improve the color shift problem.

In at least one embodiment of the present disclosure, when the microcavity orders (m in the above equation) of the microcavity structures 20 respectively corresponding to the first type of light-emitting devices R, the second type of light-emitting devices G and the third type of light-emitting devices B are the same, the thicknesses of the second electrodes 230 of the first type of light-emitting devices R, the second type of light-emitting devices G and the third type of light-emitting devices B increase sequentially. In this way, by adjusting the thicknesses of the second electrodes 230 of the light-emitting devices 200 emitting light of different colors, the cavity lengths of the microcavity structures 20 corresponding to the light-emitting devices 200 emitting light of different colors can be adjusted.

For example, the thicknesses of the second electrodes 230 are in the range of 10-40 nm. Within this numerical range, the luminance decay matching between the first type of light-emitting devices R, the second type of light-emitting devices G and the third type of light-emitting devices B is higher, thereby more effectively alleviating the color shift problem. It should be noted that, in the embodiments of the present disclosure, the thicknesses of the second electrodes 230 can be adjusted according to actual process requirements and are not limited to the numerical range.

For example, when the microcavity orders of the microcavity structures 20 respectively corresponding to the first type of light-emitting devices R, the second type of light-emitting devices G and the third type of light-emitting devices B are the same, the doping ratios of silver included in the second electrodes 230 of the first type of light-emitting devices R, the second type of light-emitting devices G and the third type of light-emitting devices B may be equal.

In at least one embodiment of the present disclosure, when the microcavity orders (m in the above equation) of the microcavity structures 20 respectively corresponding to the first type of light-emitting devices R, the second type of light-emitting devices G and the third type of light-emitting devices B are the same, if the doping ratios of silver included in the second electrodes 230 of the first type of light-emitting devices R, the second type of light-emitting devices G and the third type of light-emitting devices B are the same, the higher the microcavity orders of the microcavity structures 20, the smaller the thicknesses of the second electrodes 230 of the light-emitting devices 200 corresponding to the microcavity structures. In this way, the cost of fabricating the second electrodes 230 of the light-emitting devices 200 can be reduced, and by adjusting the thicknesses of the second electrodes 230 of the light-emitting devices 200 emitting light of different colors, the cavity lengths of the microcavity structures 20 corresponding to the light-emitting devices 200 emitting light of different colors can be adjusted.

In at least one embodiment of the present disclosure, as shown in FIG. 5A and FIG. 5B, the light-emitting device 200 may also include a cladding layer 240. The cladding layer 240 is located between the second electrode 230 and the encapsulation structure 500 and covers the second electrode 230. For example, the cladding layer 240 may be a transparent layer with a high refractive index, and the cladding layer 240 is configured to reduce light loss caused by reflection during light emission. The cladding layer 240 is located between the light-emitting device 200 and the encapsulation structure 500, thereby also contributing to forming the microcavity structure 20.

In at least one embodiment of the present disclosure, as shown in FIG. 5A and FIG. 5B, the cladding layer 240 is located within the isolation opening 301. In this way, the cladding layers 240 for the first type of light-emitting devices R, the second type of light-emitting devices G and the third type of light-emitting devices B may be separately fabricated, and the thicknesses, refractive indices and other parameters of the cladding layers 240 of the first type of light-emitting devices R, the second type of light-emitting devices G and the third type of light-emitting devices B can be separately adjusted.

In some embodiments of the present disclosure, when the microcavity orders of the microcavity structures 20 respectively corresponding to the first type of light-emitting devices R, the second type of light-emitting devices G and the third type of light-emitting devices B are the same, the thicknesses of the cladding layers 240 of the first type of light-emitting devices R, the second type of light-emitting devices G and the third type of light-emitting devices B increase sequentially. By adjusting the thicknesses of the cladding layers 240 of the light-emitting devices 200 emitting light of different colors, the cavity lengths of the microcavity structures 20 corresponding to the light-emitting devices 200 emitting light of different colors can be adjusted.

In other embodiments of the present disclosure, the higher the microcavity order of the microcavity structure 20, the smaller the thickness of the cladding layer 240 of the light-emitting device 200 corresponding to the microcavity structure.

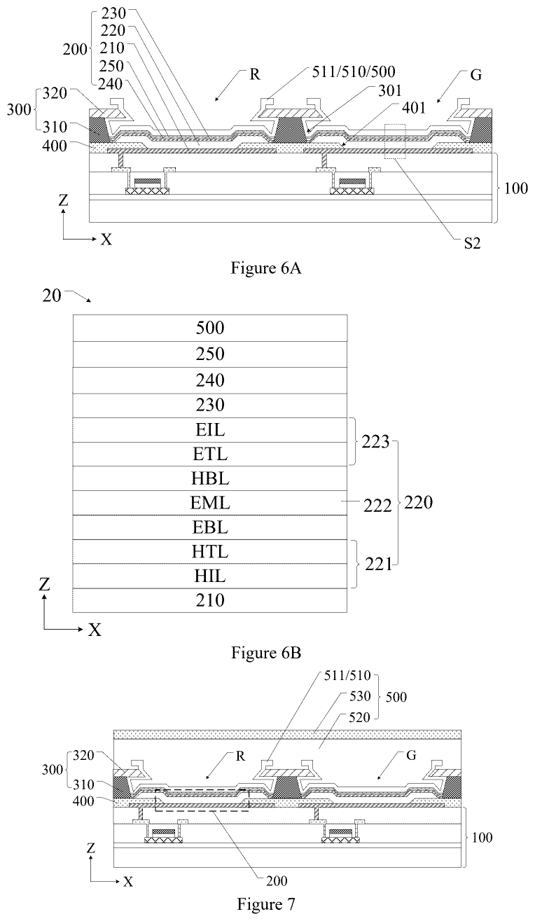

In at least one embodiment of the present disclosure, as shown in FIG. 6A and FIG. 6B, the light-emitting device 200 further includes a modulation layer 250. The modulation layer 250 is located between the cladding layer 240 and the encapsulation structure 500, and the modulation layer 250 is located within the isolation opening 301. The modulation layer 250 is configured for adjusting the reflectivity of the microcavity structure 20. For example, a material of the modulation layer 250 may include lithium fluoride.

In some embodiments of the present disclosure, when the microcavity orders of the microcavity structures 20 respectively corresponding to the first type of light-emitting devices R, the second type of light-emitting devices G and the third type of light-emitting devices B are the same, thicknesses of the modulation layers 250 of the first type of light-emitting devices R, the second type of light-emitting devices G and the third type of light-emitting devices B decrease sequentially.

In other embodiments of the present disclosure, the higher the microcavity order of the microcavity structure 20, the smaller the thickness of the modulation layer 250 of the light-emitting device 200 corresponding to the microcavity structure.

For example, the thickness of the modulation layer 250 is less than or equal to 100 nm. Within this numerical range, the luminance decay matching between the first type of light-emitting devices R, the second type of light-emitting devices G and the third type of light-emitting devices B is higher, thereby more effectively alleviating the color shift problem. It should be noted that in the embodiments of the present disclosure, the thickness of the modulation layer 250 may be adjusted according to actual process requirements and is not limited to this numerical range.

In at least one embodiment of the present disclosure, as shown in FIG. 6A, the encapsulation structure 500 includes a first encapsulation layer 510. The first encapsulation layer 510 includes encapsulation units 511 respectively corresponding to the light-emitting devices 200. The encapsulation units 511 cover the isolation openings 301 corresponding to the light-emitting devices 200. In the process of fabricating the light-emitting devices 200 in batches on the basis of the isolation structures 300, the encapsulation units 511 are synchronously formed along with the corresponding light-emitting devices 200. After each batch of the light-emitting devices 200 is fabricated, the encapsulation units 511 can provide encapsulation protection for the fabricated light-emitting devices 200 during the fabrication process of the next batch of the light-emitting devices 200, thereby ensuring the luminous effect of the light-emitting devices 200.

For example, the encapsulation units 511 respectively corresponding to adjacent light-emitting devices 200 emitting light of different colors are spaced apart from each other. Taking the sequential fabrication of the light-emitting devices R, G, and B as an example, when the light-emitting devices R are fabricated, a light-emitting device R is formed in each of the isolation openings 301, and first encapsulation layers 510 are fabricated on the display panel to cover the light-emitting devices R. Then, the first encapsulation layers 510, the second electrodes and the light-emitting functional layers in part of the isolation openings 301 (for forming the light-emitting devices G and B in a final product) are removed. In this process, the first encapsulation layers 510 serve to protect the light-emitting devices R in the other isolation openings 301 (for forming the light-emitting devices R in the final product). Based on this way, the light-emitting devices G and B are sequentially fabricated, thereby finally forming the first encapsulation layers 510 as shown in FIG. 6A. That is, the first encapsulation layers 510 on the entire display panel are fabricated by fabrication processes, and the first encapsulation layers 510 also form encapsulation units 511 spaced apart from each other. Reference may be made to the relevant description of the embodiments shown in FIG. 10A to FIG. 10H for the specific process, which is not repeated herein.

In at least one embodiment of the present disclosure, the thicknesses and/or refractive indices of the encapsulation units 511 respectively corresponding to the first type of light-emitting devices R, the second type of light-emitting devices G and the third type of light-emitting devices B are different. The encapsulation units 511 respectively corresponding to the first type of light-emitting devices R, the second type of light-emitting devices G and the third type of light-emitting devices B are fabricated in different processes, and the thicknesses, refractive indices and other parameters can be separately adjusted, thereby adjusting the cavity lengths of the microcavity structures 20.

In at least one embodiment of the present disclosure, the thicknesses of the encapsulation units 511 respectively corresponding to the first type of light-emitting devices R, the second type of light-emitting devices G, and the third type of light-emitting devices B decrease sequentially. In this way, by adjusting the thicknesses of the encapsulation units 511 corresponding to the light-emitting devices 200 emitting light of different colors, the cavity lengths of the microcavity structures 20 corresponding to the light-emitting devices 200 emitting light of different colors can be adjusted.

In at least one embodiment of the present disclosure, the refractive indices of the encapsulation units 511 respectively corresponding to the first type of light-emitting devices R, the second type of light-emitting devices G and the third type of light-emitting devices B decrease sequentially. In this way, by adjusting the refractive indices of the encapsulation units 511 corresponding to the light-emitting devices 200 emitting light of different colors, the cavity lengths of the microcavity structures 20 corresponding to the light-emitting devices 200 emitting light of different colors can be adjusted.

For example, a difference between the refractive indices of any two of the encapsulation units 511 respectively corresponding to the first type of light-emitting devices R, the second type of light-emitting devices G and the third type of light-emitting devices B is greater than or equal to 0.05. Within this numerical range, the luminance decay matching between the first type of light-emitting devices R, the second type of light-emitting devices G and the third type of light-emitting devices B is higher, thereby more effectively alleviating the color shift problem. It should be noted that, in the embodiments of the present disclosure, a difference between the thicknesses of the encapsulation units 511 respectively corresponding to the light-emitting devices 200 emitting light of different colors can be adjusted according to actual process requirements, and is therefore not limited to the above numerical range.

In at least one embodiment of the present disclosure, as shown in FIG. 7, the encapsulation structure 500 further includes a second encapsulation layer 520 and a third encapsulation layer 530. The second encapsulation layer 520 and the third encapsulation layer 530 are located on a side of the first encapsulation layer 510 away from the substrate 100 and cover the first encapsulation layer 510 and the isolation structure 300. The second encapsulation layer 520 is located between the first encapsulation layer 510 and the third encapsulation layer 530. For example, the first encapsulation layer 510 and the third encapsulation layer 530 are inorganic film layers, the second encapsulation layer 520 is an organic film layer, and the second encapsulation layer 520 can improve the flatness of the surface of the display panel, thereby facilitating the provision of other components (for example, a touch structure described below) on the encapsulation structure 500. In addition, the second encapsulation layer 520 can have a certain flexibility to mitigate stresses in the first encapsulation layer 510 and the third encapsulation layer 530, thereby improving the reliability of the display panel and facilitating the application of the display panel in the field of flexible displays. Furthermore, the third encapsulation layer 530 has high compactness, provides a high barrier effect against water, oxygen, etc., and the third encapsulation layer 530 has higher strength, thereby facilitating the fabrication of other components (for example, touch function-related structures, optical film layers, etc.) thereon.

In at least one embodiment of the present disclosure, as shown in FIG. 7, the refractive indices of portions of the second encapsulation layer 520 and the third encapsulation layer 530 respectively corresponding to the first type of light-emitting devices R, the second type of light-emitting devices G and the third type of light-emitting devices B are equal, that is, the second encapsulation layer 520 and the third encapsulation layer 530 are formed over the entire surface, thereby maintaining the integrity of the film layers to ensure the encapsulation effect of the encapsulation structure 500.

In the embodiments of the present disclosure, for the principle of determining parameters of each film layer of the microcavity structure 20 corresponding to the light-emitting device 200 based on the wavelength of the light-emitting device 200, reference may be made to Equations 3 to 6 below.

$$Equation 3$$

$$I ( λ , θ ) = \frac{{T}_{t} [ 1 + {R}_{b} + 2 \sqrt{{R}_{b}} cos ( - {φ}_{b} + \frac{4 π nz cos ( {θ}_{org , EML} )}{λ} ) ]}{{( 1 - \sqrt{{R}_{b} {R}_{t}} )}^{2} + 4 \sqrt{{R}_{b} {R}_{t}} {sin}^{2} ( \frac{Δ ϕ}{2} )} {I}_{0} ( λ )$$

$$Δφ = - {φ}_{b} - {φ}_{t} + {\sum }_{i} \frac{4 π {n}_{i} {d}_{i} cos ( {θ}_{org , i} )}{λ} \qquad Equation 4$$

$$Δφ = m \times 2 π \qquad Equation 5$$

$$2 L = \frac{Δφλ}{2 π} = m λ \qquad Equation 6$$

In the above Equations 3 to 6, I(λ, θ) and I₀(λ) are spectra, where λ is a wavelength of outgoing light corresponding to the light-emitting device 200, and θ is an emission angle (viewing angle) of a sub-pixel where the light-emitting device 200 is located; T is the transmittance of the second electrode 230; R_{b} is the reflectivity of the first electrode 210; Rₜ is the reflectivity of the second electrode 230; n is a positive integer; z is the distance between the film layer and the second electrode 230; θ_{org,EML} is an emission angle of the light-emitting device 200; Δψ is the phase of light for one round trip in a microcavity; φ_{b} is the reflection phase shift of the first electrode 210; φₜ is the reflection phase shift of the second electrode 230; nᵢ is the refractive index of the film layer; dᵢ is the thickness of the film layer; θ_{org,i} is an observation angle [to be added]; m is a mode order (order); L is the total optical length of the microcavity. For example, for a second order microcavity of 460 nm wavelength, m=2, λ=460 nm, and L=460 nm.

In at least one embodiment of the present disclosure, referring again to FIG. 2 and FIG. 3, the isolation structure 300 includes a support portion 310 and a crown portion 320. The support portion 310 is located between the substrate 100 and the crown portion 320. The support portion 310 is a conductive structure, and a side surface of the support portion 310 is connected to an edge portion of the second electrode 230. An orthographic projection of an end of the support portion 310 facing the crown portion 320 on the substrate 100 is located within an orthographic projection of the crown portion 320 on the substrate 100. In this way, the support portion 310 can be used for assisting in connecting the second electrode 230. Since the support portion 310 is located at a gap between the light-emitting devices 200, the support portion can be designed with a greater thickness (thicker than the second electrode 230) and can be fabricated using a material with high electrical conductivity. Therefore, when connected to the second electrode 230, the support portion can alleviate the problem of voltage drop across the second electrode 230 when the light-emitting devices 200 are driven. In addition, during the fabrication of the light-emitting devices 200, the isolation effect of the isolation structure 300 on the light-emitting functional layer 220 can be enhanced, thereby reducing the risk of current crosstalk between different light-emitting devices 200.

In at least one embodiment of the present disclosure, referring again to FIG. 2 and FIG. 3, an orthographic projection of the support portion 310 on the substrate 100 is located within the orthographic projection of the crown portion 320 on the substrate 100. In this way, the isolation structure 300 generally presents a shape that is wider at the top and narrower at the bottom. Therefore, during the evaporation of part of film layers of the light-emitting device 200 (e.g., the light-emitting functional layer 220 and the second electrode 230 mentioned in the above embodiments), by controlling an evaporation angle for each film layer, and under the blocking effect of the isolation structure 300, it is possible to ensure that an edge of a portion of the film layer (e.g., the second electrode 230 above) can be connected to the conductive structure of the isolation structure 300 (e.g., the support portion 310), while preventing another portion of the film layer (for example, the light-emitting functional layer or a portion of the film layer including a hole material, i.e., the first functional layer 221) from coming into contact with the isolation structure 300. In this way, while isolating a portion of the film layer (including electrical isolation, and the light-emitting functional layers or portions of film layers of adjacent light-emitting devices are not directly or indirectly electrically connected), it is ensured that another portion of the film layer (for example, the above second electrode 230) can be connected to the conductive structure of the isolation structure 300.

In at least one embodiment of the present disclosure, referring again to FIG. 2 and FIG. 3, the orthographic projection of the surface of the support portion 310 facing the crown portion 320 on the substrate 100 is located within the orthogonal projection of the surface of the support portion 310 facing the substrate 100 on the substrate 100. In this way, the support portion 310 generally presents a shape that is wider at the bottom and narrower at the top, thereby forming a relatively inclined side surface. This facilitates the deposition of an edge portion of the second electrode 230 on the side surface of the support portion 310 to increase the thickness of the portion of the second electrode 230 in contact with the support portion 310, thereby reducing the impedance at the connection between the support portion 310 and the second electrode 230.

In at least one embodiment of the present disclosure, referring again to FIG. 2 and FIG. 3, the display panel may further include a pixel defining layer 400. The pixel defining layer 400 includes pixel openings 401 respectively corresponding to the isolation openings 301, and the pixel openings 401 are in communication with the corresponding isolation openings 301. The isolation openings 301 and the corresponding pixel openings 401 together limit the light-emitting functional layers 220 and the second electrodes 230 of the light-emitting devices 200. For example, the pixel defining layer 400 is located between the isolation structure 300 and the substrate 100.

In at least one embodiment of the present disclosure, as shown in FIG. 2 and FIG. 3, the pixel defining layer 400 may be an inorganic film layer. In the case that the light-emitting devices 200 are fabricated using the isolation structure 300, the pixel defining layer 400 does not need to have a large thickness to accommodate and partition part of the film layers of the light-emitting device 200, and the pixel defining layer 400 can be fabricated directly using an inorganic material. Thus, the pixel defining layer 400 can separate the isolation structure 300 from the first electrode 210, and a smaller gap is designed between the first electrodes 210. This reduces the gap between the pixels, thereby increasing the pixels-per-inch (PPI) of the display panel; In addition, the inorganic layer has high compactness and high resistivity, thereby reducing the design thickness of the display panel. Furthermore, the thickness of the inorganic film layer is relatively small, which makes the pixel opening 401 have a small depth, to ensure the continuity of the film layer (e.g., the second electrode 230) formed at the pixel opening 401. Furthermore, as an inorganic film layer, the pixel defining layer 400 has a strong bonding strength with the isolation structure 300, thereby reducing the risk of detachment of the isolation structure 300.

In at least one embodiment of the present disclosure, as shown in FIG. 2 and FIG. 3, an orthogonal projection of the pixel opening 401 on the substrate 100 is located within an orthogonal projection of the first electrode 210 of a corresponding light-emitting device 200 on the substrate 100, and an edge portion of the first electrode 210 is located between the pixel defining layer 400 and the isolation structure 300. In this way, the pixel defining layer 400 is used for separating the first electrode 210 from the isolation structure 300 to prevent short circuits.

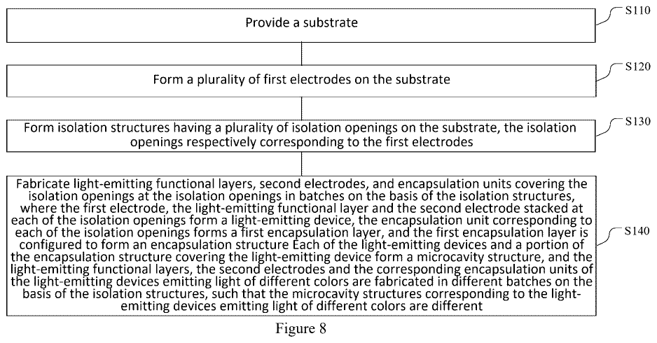

At least one embodiment of the present disclosure provides a fabrication method for a display panel, which may include steps S110 to S140 as shown in FIG. 8, specifically as follows.

In step S110, a substrate provided.

In step S120, first electrodes are formed on the substrate.

In step S130, isolation structures having isolation openings are formed on the substrate, the isolation openings corresponding to the first electrodes, respectively.

In step S140, light-emitting functional layers, second electrodes, and encapsulation units covering the isolation openings are fabricated in batches at the isolation openings on the basis of the isolation structure, where a first electrode, a light-emitting functional layer and a second electrode stacked at each isolation opening form a light-emitting device, the encapsulation unit corresponding to each isolation opening for a first encapsulation layer, and the first encapsulation layer is configured to form an encapsulation structure. Each light-emitting device and a portion of the encapsulation structure covering the light-emitting device form a microcavity structure, and the light-emitting functional layers, the second electrodes and corresponding encapsulation units of the light-emitting devices emitting light of different colors are fabricated in different batches on the basis of the isolation structure, and the microcavity structures corresponding to the light-emitting devices emitting light of different colors are different.

In the display panel fabricated in steps S110 to S140, on the basis of the isolation structures, each film layer of the microcavity structures in which the light-emitting devices emitting light of different colors are located can be fabricated with parameters (including thickness, refractive index, etc.), respectively, thereby the microcavity length of each microcavity structure can be adjusted, improving chromaticity, light extraction efficiency, and so forth of sub-pixels in which the microcavity structures are located (the light-emitting devices serve as physical light-emitting structures thereof), to solve the problem of color shift of the display panel and improve the light extraction efficiency of the display panel. For the structure of the display panel obtained by the fabrication method, reference may be made to the relevant descriptions of the foregoing embodiments, which will not be repeated herein.

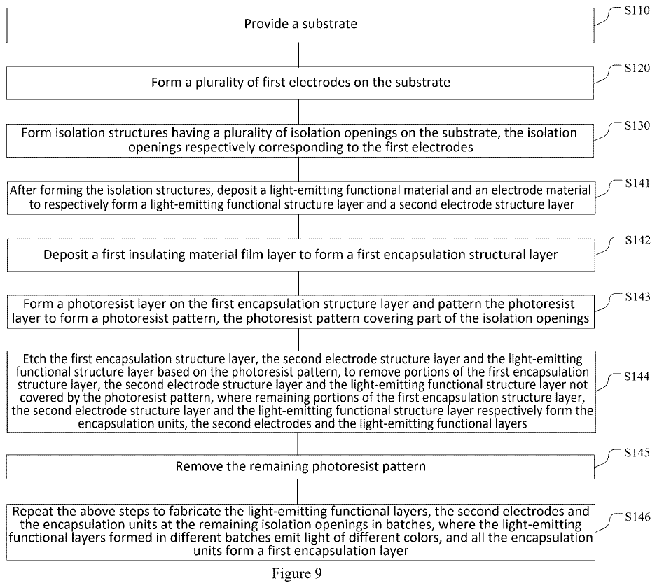

In the fabrication method for a display panel according to in at least one embodiment of the present disclosure, as shown in FIG. 9, the above step S140 may include the following steps S141 to S146.

In step S141, after forming the isolation structures, a light-emitting functional material and an electrode material are deposited to respectively form a light-emitting functional structure layer and a second electrode structure layer.

In step S142, a first insulating material film layer is deposited to form a first encapsulation structure layer.

In step S143, a photoresist layer formed on the first encapsulation structure layer and the photoresist layer is patterned to form a photoresist pattern, the photoresist pattern covering part of the isolation openings.

In step S144, the first encapsulation structure layer, the second electrode structure layer and the light-emitting functional structure layer are etched based on the photoresist pattern, to remove portions of the first encapsulation structure layer, the second electrode structure layer and the light-emitting functional structure layer not covered by the photoresist pattern, where remaining portions of the first encapsulation structure layer, the second electrode structure layer and the light-emitting functional structure layer respectively form the encapsulation units, the second electrodes and the light-emitting functional layers.

In step S145, the remaining photoresist pattern is removed.

In step S146, the above steps are repeated to fabricate the light-emitting functional layers, the second electrodes and the encapsulation units at the remaining isolation openings in batches, where the light-emitting functional layers formed in different batches emit light of different colors, and all the encapsulation units form a first encapsulation layer.

For the structure of the display panel obtained in the above steps S141 to S146, the problems solved, corresponding effects, and possible further improvements, reference may be made to the relevant descriptions of the foregoing embodiments, which will not be repeated herein.

In the fabrication method for a display panel according to at least one embodiment of the present disclosure, the light-emitting devices are classified into a first type of light-emitting devices, a second type of light-emitting devices and a third type of light-emitting devices emitting light of different colors. In different batches, the thicknesses, and/or materials, and/or refractive indices of at least one of the encapsulation units, the second electrodes, and the light-emitting functional layers of the first type of light-emitting devices, the second type of light-emitting devices and the third type of light-emitting devices are controlled, respectively, and the microcavity structures corresponding to the first type of light-emitting devices, the second type of light-emitting devices and the third type of light-emitting devices have different microcavity lengths. For the structure of the display panel obtained by the fabrication method, the problems solved, corresponding effects, and possible further improvements, reference may be made to the relevant descriptions of the foregoing embodiments, which will not be repeated herein.

The preparation process of the display panel shown in FIG. 6A will be described with respect with FIGS. 10A to 10H hereinafter, in order to show directly how the display panel is fabricated and the principle of the isolation structures increasing the pixels-per-inch PPI.

As shown in FIG. 10A, a substrate 100 is provided, and first electrodes 210 arranged in an array are formed on the substrate 100.

As shown in FIG. 10B, an inorganic material is deposited on the substrate 100 on which the first electrodes 210 are formed to form a pixel-defining material film layer 400a.

As shown in FIG. 10C, a first material layer 310a and a second material layer 320a are formed on the pixel-defining material film layer 400a. For example, a material of the first material layer 310a may be aluminum, and a material of the second material layer 320a may be titanium.

As shown in FIG. 10D, the first material layer 310a and the second material layer 320a are subjected to a patterning process and the first material layer 310a is formed as the support portion 310, and the second material layer 320a is formed as the crown portion 320. The support portion 310 and the crown portion 320 define an isolation opening 301 and form the isolation structure 300. For the specific structure of the isolation structure 300, reference may be made to the descriptions of the foregoing embodiments, which will not be repeated herein.

In the embodiments of the present disclosure, the patterning process may be a photolithographic patterning process, which, for example, may include: coating a photoresist on a structure layer to be patterned, exposing the photoresist using a mask, developing the exposed photoresist to obtain a photoresist pattern, etching (in one embodiment wet or dry etching) the structure layer using the photoresist pattern, and then, in one embodiment, removing the photoresist pattern. It should be noted that when the material of the structure layer (e.g., a photoresist pattern 600 described below) includes photoresist, the structure layer may be directly exposed by means of the mask to form the desired pattern.

It should be noted that if a corrosion resistance of the second material layer 320a (e.g., titanium) is greater than a corrosion resistance of the first material layer 310a (e.g., aluminum), an etching rate of the first material layer 310a may be higher than an etching rate of the second material layer 320a. As a result, a width of the crown portion 320 may be greater than a width of the support portion 310, thereby forming the structure as shown in FIG. 10D.

As shown in FIG. 10E, the pixel-defining material film layer 400a is patterned to form a pixel opening 401 at a location where a portion of the isolation opening 301 is located, and the pixel-defining material film layer 400a is formed as the pixel defining layer 400 (non-final form). In this way, during the process, the pixel defining layer 400 still exists at a portion of the isolation openings 301, to protect the underlying first electrodes 210 during subsequent etching processes.

It should be noted that in the step shown in FIG. 10E, the pixel openings 401 can be formed by a photolithographic patterning process. In this process, the isolation structure 300 can also be used to expose the photoresist, thereby accurately controlling the positions in which the pixel openings 401 are formed.

As shown in FIG. 10F, a light-emitting functional material layer, an electrode material layer, a cladding material layer and a modulation material layer are evaporated on the substrate 100 to form the light-emitting device 200 in each of the isolation openings 301 of the isolation structures 300. No mask is used in the evaporation in this process, so the evaporated material can also be deposited on the crown portion 320. It should be noted that in a practical process, the evaporated material will be deposited at an upper surface of the crown portion 320 away from the substrate 100 and on side walls (not shown). A first encapsulation film 510a is then formed by deposition to cover the light-emitting device 200 and the isolation structure 300. The light-emitting devices 200 formed during this process all emit blue light B.

As shown in FIG. 10G, the photoresist is formed (e.g., coated) on the substrate 100 on which the first encapsulation film 510a is formed, and then is subjected to a patterning process to form a photoresist pattern 600. The photoresist pattern 600 covers only part of the isolation openings 301 of the isolation structures 300 (the isolation openings 301 corresponding to the pixel openings 401).

As shown in FIG. 10H, the photoresist pattern 600 is used as a mask to etch a surface of the display panel, to remove the portions of the first encapsulation film 510a, the cladding material layer, the modulation material layer, the electrode material layer and the light-emitting functional material layer that are not covered by the photoresist pattern 600. The remaining portions of the first encapsulation film 510a form the encapsulation units 511 of the first encapsulation layer 410. The remaining photoresist pattern 600 is then removed.

As shown in FIG. 10I, the pixel defining layer 400 is patterned to form pixel openings 401 at positions corresponding to the other part of the isolation openings 301 (at which no pixel opening 401 is formed).

The above steps of FIG. 10E to FIG. 10H are repeated to form light-emitting devices 200 that emit red light R and light-emitting devices 200 that emit green light G, respectively, in the other isolation openings 301, and to form a display panel as shown in FIG. 6A.

At least one embodiment of the present disclosure provides a display device, which includes the display panel mentioned in any one of the foregoing embodiments.

For example, the display device may be a TV set, a digital camera, a cell phone, a watch, a tablet computer, a laptop computer, a navigator, or any other product or component having a display function.

It should be understood that the steps may be reordered, added, or deleted using the various forms of processes illustrated above. For example, the steps recorded in the present disclosure may be performed in parallel, sequentially, or in a different order, provided that the desired results of the embodiments of the present disclosure can be achieved, which are not limited here.

The detailed description of the above embodiments does not constitute a limitation on the scope of protection of the present disclosure. It should be understood that various modifications, combinations, sub-combinations, and substitutions can be made based on design requirements and other factors. Any modifications, equivalent substitutions, or improvements made within the spirit and principle of the present disclosure should be included within the scope of protection of the present disclosure.

The above descriptions are merely some embodiments of the specification, but are not intended to limit the specification, and any modifications, equivalent replacements, etc. made within the spirit and principle of the specification should be included within the scope of protection of the specification.

1. A display panel, comprising:
a substrate;
a plurality of light-emitting devices located on the substrate;
isolation structures located on the substrate and comprising a plurality of isolation openings, at least part of film layers of the light-emitting devices being located in the isolation opening; and
encapsulation structures located on sides of the isolation structures away from the substrate and covering the light-emitting devices,
wherein each of the light-emitting devices and a portion of the encapsulation structure covering the light-emitting device form a microcavity structure, and the light-emitting devices emitting light of different colors correspond to different microcavity structures.

2. The display panel according to claim 1, wherein each of the light-emitting devices comprises a first electrode, a light-emitting functional layer and a second electrode which are sequentially stacked on the substrate, the light-emitting functional layer and the second electrode of the light-emitting device are located in a corresponding one of the isolation openings;
the microcavity structures corresponding to the light-emitting devices emitting light of different colors have different microcavity lengths;
or a length of the microcavity structure corresponding to the light-emitting device is an integral multiple of half a wavelength of light generated by the light-emitting device.

3. The display panel according to claim 2, wherein the plurality of light-emitting devices are classified into a first type of light-emitting devices, a second type of light-emitting devices and a third type of light-emitting devices which emit light of different colors, and wavelengths of light emitted by the first type of light-emitting devices, the second type of light-emitting devices and the third type of light-emitting devices decrease sequentially.

4. The display panel according to claim 3, wherein thicknesses of the second electrodes of the first type of light-emitting devices, the second type of light-emitting devices and the third type of light-emitting devices are different.

5. The display panel according to claim 3, wherein the second electrode comprises magnesium and silver, and doping ratios of silver comprised in the second electrodes of the first type of light-emitting devices, the second type of light-emitting devices, and the third type of light-emitting devices are different.

6. The display panel according to claim 5, wherein the doping ratios of silver comprised in the second electrodes of the first type of light-emitting devices, the second type of light-emitting devices and the third type of light-emitting devices increase sequentially; and a content ratio of magnesium to silver comprised in the second electrode ranges from 1/10 to 10.

7. The display panel according to claim 3, wherein microcavity orders of the microcavity structures corresponding to the first type of light-emitting devices, the second type of light-emitting devices and the third type of light-emitting devices are the same, and thicknesses of the second electrodes of the first type of light-emitting devices, the second type of light-emitting devices and the third type of light-emitting devices are the same.

8. The display panel according to claim 3, wherein the higher a microcavity order of the microcavity structure, the smaller a doping ratio of silver in the second electrode of the light-emitting device corresponding to the microcavity structure.

9. The display panel according to claim 4, wherein when microcavity orders of the microcavity structures respectively corresponding to the first type of light-emitting devices, the second type of light-emitting devices and the third type of light-emitting devices are the same, thicknesses of the second electrodes of the first type of light-emitting devices, the second type of light-emitting devices and the third type of light-emitting devices increase sequentially.

10. The display panel according to claim 4, wherein
when doping ratios of silver comprised in the second electrodes of the first type of light-emitting devices, the second type of light-emitting devices and the third type of light-emitting devices are the same, the higher the microcavity order of the microcavity structure, the smaller the thickness of the second electrode of the light-emitting device corresponding to the microcavity structure.

11. The display panel according to claim 4, wherein the light-emitting device comprises at least one light-emitting functional layer, the light-emitting functional layer comprising a hole injection layer, a hole transport layer, an electron blocking layer, a light-emitting layer, a hole blocking layer, an electron transport layer and an electron injection layer which are sequentially stacked from the first electrode to the second electrode;
the light-emitting device comprises only one light-emitting functional layer; or
the light-emitting device comprises at least two stacked light-emitting functional layers, and a charge generation layer is provided between adjacent light-emitting functional layers of the light-emitting device.

12. The display panel according to claim 3, wherein the light-emitting device further comprises a cladding layer located between the second electrode and the encapsulation structure and covers the second electrode;
when microcavity orders of the microcavity structures respectively corresponding to the first type of light-emitting devices, the second type of light-emitting devices and the third type of light-emitting devices are the same, thicknesses of the cladding layers of the first type of light-emitting devices, the second type of light-emitting devices and the third type of light-emitting devices increase sequentially; or
the higher the microcavity order of the microcavity structure, the smaller the thickness of the cladding layer of the light-emitting device corresponding to the microcavity structure.

13. The display panel according to claim 12, wherein the light-emitting device further comprises a modulation layer, the modulation layer being located between the cladding layer and the encapsulation structure and being located within the isolation opening; when the microcavity orders of the microcavity structures respectively corresponding to the first type of light-emitting devices, the second type of light-emitting devices and the third type of light-emitting devices are the same, thicknesses of the modulation layers of the first type of light-emitting devices, the second type of light-emitting devices and the third type of light-emitting devices decrease sequentially; or
the higher the microcavity order of the microcavity structure, the smaller the thickness of the modulation layer of the light-emitting device corresponding to the microcavity structure.

14. The display panel according to claim 3, wherein the encapsulation structure comprises a first encapsulation layer, the first encapsulation layer comprising a plurality of encapsulation units respectively corresponding to the light-emitting devices, and the encapsulation units covering the isolation openings corresponding to the light-emitting devices.

15. The display panel according to claim 14, wherein thicknesses of the encapsulation units respectively corresponding to the first type of light-emitting devices, the second type of light-emitting devices and the third type of light-emitting devices decrease sequentially.

16. The display panel according to claim 14, wherein refractive indices of the encapsulation units respectively corresponding to the first type of light-emitting devices, the second type of light-emitting devices and the third type of light-emitting devices decrease sequentially; and
a difference between the refractive indices of any two of the encapsulation units respectively corresponding to the first type of light-emitting devices, the second type of light-emitting devices and the third type of light-emitting devices is greater than or equal to 0.05.

17. The display panel according to claim 2, wherein the isolation structure comprises a support portion and a crown portion, the support portion being disposed between the substrate and the crown portion, the support portion being a conductive structure and being connected to the second electrode, and an orthographic projection of the support portion on the substrate being located within an orthographic projection of the crown portion on the substrate;
the display panel further comprises a pixel defining layer, the pixel defining layer comprises pixel openings respectively corresponding to the isolation openings, and the pixel openings are in communication with the corresponding isolation openings; and the isolation openings and the corresponding pixel openings together limit the light-emitting functional layers and the second electrodes of the light-emitting devices.

18. A fabrication method for a display panel, comprising:
providing a substrate;
forming a plurality of first electrodes on the substrate;
forming isolation structures having a plurality of isolation openings on the substrate, the isolation openings respectively corresponding to the first electrodes; and fabricating light-emitting functional layers, second electrodes, and encapsulation units covering the isolation openings at the isolation openings in batches on the basis of the isolation structures, wherein the first electrode, the light-emitting functional layer and the second electrode stacked at each of the isolation openings form a light-emitting device, the encapsulation unit corresponding to each of the isolation openings forms a first encapsulation layer, and the first encapsulation layer is configured to form an encapsulation structure,
wherein each of the light-emitting devices and a portion of the encapsulation structure covering the light-emitting device form a microcavity structure, and the light-emitting functional layers, the second electrodes and the corresponding encapsulation units of the light-emitting devices emitting light of different colors are fabricated in different batches on the basis of the isolation structures, wherein the microcavity structures corresponding to the light-emitting devices emitting light of different colors are different.

19. The fabrication method according to claim 18, wherein fabricating light-emitting functional layers, second electrodes, and encapsulation units covering the isolation openings at the isolation openings in batches on the basis of the isolation structure comprises:
after forming the isolation structures, depositing a light-emitting functional material and an electrode material to respectively form a light-emitting functional structure layer and a second electrode structure layer;
depositing a first insulating material film layer to form a first encapsulation structure layer;
forming a photoresist layer on the first encapsulation structure layer and patterning the photoresist layer to form a photoresist pattern, the photoresist pattern covering part of the isolation openings;
etching the first encapsulation structure layer, the second electrode structure layer and the light-emitting functional structure layer based on the photoresist pattern, to remove portions of the first encapsulation structure layer, the second electrode structure layer and the light-emitting functional structure layer not covered by the photoresist pattern, wherein remaining portions of the first encapsulation structure layer, the second electrode structure layer and the light-emitting functional structure layer respectively form the encapsulation units, the second electrodes and the light-emitting functional layers;
removing a remaining portion of the photoresist pattern; and
repeating the above steps to fabricate the light-emitting functional layers, the second electrodes and the encapsulation units at the remaining isolation openings in batches, wherein the light-emitting functional layers formed in different batches emit light of different colors, and all of the encapsulation units for a first encapsulation layer.

20. A display device, comprising:
a display panel, comprising:
a substrate;
a plurality of light-emitting devices located on the substrate;
isolation structures located on the substrate and comprising a plurality of isolation openings, at least part of film layers of the light-emitting devices being located in the isolation opening; and
encapsulation structures located on sides of the isolation structures away from the substrate and covering the light-emitting devices,
wherein each of the light-emitting devices and a portion of the encapsulation structure covering the light-emitting device form a microcavity structure, and the light-emitting devices emitting light of different colors correspond to different microcavity structures.
